(19) United States
(12) Patent Application Publication
(10) Pub. No.: US 2022/0259722 A1
(43) Pub. Date: Aug. 18, 2022

(54) SUBSTRATE SURFACE MODIFIER FOR ATOMIC LAYER DEPOSITION AND METHOD FOR MODIFYING SURFACE OF SUBSTRATE USING THE SAME

(71) Applicant: DONGJIN SEMICHEM CO., LTD., Incheon (KR)

(72) Inventors: Tae Wook KIM, Hwaseong-si (KR); Jae Woo LEE, Hwaseong-si (KR); Cheol Kyu BOK, Hwaseong-si (KR); Jun Young KIM, Hwaseong-si (KR); So Jeong YEO, Hwaseong-si (KR); Man Ho HAN, Hwaseong-si (KR)

(21) Appl. No.: 17/731,729

(22) Filed: Apr. 28, 2022

Related U.S. Application Data
(63) Continuation of application No. PCT/KR2020/015361, filed on Nov. 5, 2020.

(30) Foreign Application Priority Data
Nov. 11, 2019 (KR) 10-2019-0143703
Nov. 4, 2020 (KR) 10-2020-0145671

(51) Int. Cl. C23C 16/02; C23C 16/30; C23C 16/34; C23C 16/18; C23C 16/44

(52) U.S. Cl. CPC C23C 16/0272; C23C 16/308; C23C 2222/20; C23C 16/18; C23C 16/4408; C23C 16/34

(57) ABSTRACT

This invention relates to a surface modifier for uniformly modifying the surface of a substrate such as an inorganic thin film, using atomic layer deposition or chemical vapor deposition, and a method for modifying the surface of a substrate using the same.

### CROSS-REFERENCE TO RELATED APPLICATION(S)

This application is a Continuation of International Application No. PCT/KR2020/015361 filed on Nov. 5, 2020, which claims priority from Korean Patent Application No. 10-2019-0143703 filed on Nov. 11, 2019 and Korean Patent Application No. 10-2020-0145671 filed on Nov. 4, 2020, the disclosures of which are herein incorporated by reference in their entireties.

### TECHNICAL FIELD

This invention relates to a substrate surface modifier and a method for modifying the surface of a substrate using the same, and more specifically, to a surface modifier for modifying the surface of a substrate such as an inorganic thin film, using atomic layer deposition or chemical vapor deposition, and a method for modifying the surface of a substrate using the same.

### BACKGROUND

A highly developed semiconductor manufacturing process involves many operations of producing thin films of various properties and forms, and partially or wholly removing the produced thin film. When producing a thin film, many properties should be considered, and for example, it is essential in the manufacture of semiconductor devices to secure bonding strength between thin films consisting of heterogeneous materials. Specifically, in case sufficient bonding strength between adjacent organic film and inorganic film is required, such as in a photolithography process, the surface of the inorganic film should be coated with a bonding accelerator such as hexamethyldisilazane (HMDS) to increase bonding strength between the inorganic film and organic film. Such a modification process of an inorganic film is generally coating of a modifier on the surface of the inorganic film by spin coating. However, if a modifier is coated on the surface of an inorganic film by a common coating process, it is difficult to obtain a modified thin film with a uniform thickness and high density due to process properties. Recently, with continuous miniaturization of semiconductor processes, standards of the processes and material used are becoming more and more strict, and thus there is a demand for development of a novel process capable of securing a process margin.

Meanwhile, with an increasing demand for high quality thin film deposition for fine control of a thin film thickness and response to a complicated form, and the like in the recent thin film deposition process, atomic layer deposition (ALD) or chemical vapor deposition (CVD) is being introduced more and more. In case surface modification is required for a thin film deposited by atomic layer deposition or chemical vapor deposition, a process of transferring a substrate on which a thin film is deposited to a separate device for depositing a modification layer (track process) and depositing a modification layer is conducted. Such a process is complicated, and should transfer a substrate from ALD or CVD equipment to a device for depositing a modification layer.

In addition, in order to modify a substrate, a track process such as spin coating is conducted to form an organic polymer film on the substrate. However, since the existing organic polymer film for surface modification corresponds to physical surface modification, surface modification is limited, and fine tuning is difficult.

In addition, in the conventional CVD/ALD process, liquid polymer compounds were mainly used for surface modification. However, since the liquid polymer compounds have low volatility and high viscosity, a CVD/ALD process can not be progressed, and equipment may be damaged and thus the process itself may not be progressed.

### SUMMARY

It is an object of the invention to provide a substrate surface modifier for atomic layer deposition and chemical vapor deposition that can more uniformly modify the surface of a substrate, and more easily control the modification process of a substrate surface, and a method for modifying the surface of a substrate using the same.

It is another object of the invention to provide a substrate surface modifier for atomic layer deposition and chemical vapor deposition, and a method for modifying the surface of a substrate using the same, wherein a thin film deposition process by atomic layer deposition or chemical vapor deposition and the subsequent surface modification process can be progressed with the same equipment.

There is provided herein a substrate surface modifier for atomic layer deposition or chemical vapor deposition represented by the following Chemical Formula 1:

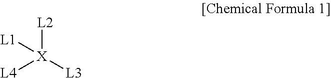

in Chemical Formula 1,

X is Si, Ge, Ti, W, Co, Al, Ni, Ru, Cu, Ta, Sn, Hf, La, Mn, Ga, In, or Zr,

L1, L2, L3, and L4 are each independently the ligand of X, and at least one of the L1, L2, L3, and L4 includes a functional group modifying the surface of a substrate, and at least one other of the L1, L2, L3, and L4 includes a functional group bonding to the surface of a substrate.

There is also provided herein a method for modifying the surface of a substrate consisting of steps of: placing a substrate in a deposition chamber, and then supplying a substrate surface modifier in the form of a gas to the deposition chamber, to form a surface modification layer formed by the substrate surface modifier on the surface of the substrate; and supplying a purge gas to the deposition chamber to remove a surplus of the substrate surface modifier.

According to the substrate surface modifier for atomic layer deposition or chemical vapor deposition and a method for modifying a substrate surface using the same of the invention, the surface of a substrate can be more uniformly modified, and the modification process of a substrate surface can be more easily controlled.

In addition, a surface modification layer can be easily formed on an inorganic film as a target, instead of an organic polymer film for surface modification that was previously realized by spin coating, and the like. Furthermore, according to the invention, by using a monomolecular compound having high volatility as a surface modifier, a half cycle process can be applied instead of the existing full cycle process during the atomic layer deposition or chemical vapor deposition process, thereby improving processability.

Moreover, according to the invention, a thin film deposition process by atomic layer deposition or chemical vapor deposition and the subsequent surface modification process can be continuously processed in the same equipment.

### BRIEF DESCRIPTION OF THE DRAWINGS

FIG. 1 shows the modified state of a substrate modified with the substrate surface modifier according to an exemplary embodiment of the invention.

FIG. 2 shows a method for modifying a substrate surface using the substrate surface modifier according to an exemplary embodiment of the invention.

FIG. 3 shows the experimental result of water contact angle to a silicon substrate.

FIG. 4 is a graph showing the experimental result of water contact angle according to the deposition number of the substrate surface modifier according to an exemplary embodiment of the invention.

### DETAILED DESCRIPTION

Hereinafter, a surface modifier and a method for modifying a substrate surface using the same according to the invention will be explained in detail, with reference to the attached drawings.

The terms used herein are only to explain specific embodiments, and are not intended to limit the invention. A singular expression includes a plural expression thereof, unless it is expressly stated or obvious from the context that such is not intended.

As used herein, the terms “comprise”, “equipped”, or “have”, etc. are intended to designate the existence of practiced characteristic, number, step, constructional element, or combinations thereof, and they are not intended to preclude the possibility of existence or addition of one or more other characteristics, numbers, steps, constructional elements, or combinations thereof.

Although various modifications can be made to the invention and the invention may have various forms, specific examples will be illustrated and explained in detail below. However, it should be understood that these are not intended to limit the invention to a specific disclosure, and that the invention includes all the modifications, equivalents, or replacements thereof without departing from the spirit and technical scope of the invention.

In addition, as used herein, a contact angle means a contact angle of a substrate surface to water. Namely, the contact angle may be measured by measuring a static contact angle of the outermost surface of a substrate or thin film, of which the contact angle is to be measured, to 3 μl of water (ultrapure water), using an image digital contact angle measuring instrument (KROSS Scientific DSA 100).

In addition, as used herein, a full cycle may mean conducting a 4-step process of supplying a precursor to a deposition chamber, purging, supplying a reactant, and purging, during an atomic layer deposition or chemical vapor deposition process (CVD/ALD process).

In addition, as used herein, a half cycle may mean conducting a 2-step process of supplying a substrate surface modifier for forming a surface modification layer to a deposition chamber containing a thin film (substrate) of which the surface is to be modified, and supplying a purge gas for removing a surplus of the substrate surface modifier.

First, there is provided herein a substrate surface modifier for atomic layer deposition or chemical vapor deposition represented by the following Chemical Formula 1:

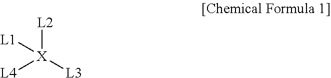

in Chemical Formula 1,

X is Si, Ge, Ti, W, Co, Al, Ni, Ru, Cu, Ta, Sn, Hf, La, Mn, Ga, In, or Zr,

L1, L2, L3, and L4 are each independently the ligand of X, and at least one of the L1, L2, L3, and L4 includes a functional group modifying the surface of a substrate, and at least one other of the L1, L2, L3, and L4 includes a functional group bonding to the surface of a substrate.

In case the existing organic polymer film for surface modification is used, there is a limit due to the physical surface modification method.

Thus, the invention is characterized by providing a monomolecular compound (precursor) represented by Chemical Formula 1 as a substrate surface modifier. In addition, the surface modifier of the invention is not used as a simple thin film, but is used for hydrophobic or hydrophilic modification of a substrate surface,

In addition, the invention is also characterized by providing a novel surface modification method using a half cycle process, during an atomic layer deposition or chemical vapor deposition process (CVD/ALD process), instead of a spin coating process.

Namely, in a semiconductor process, a CVD/ALD process is generally a full cycle, and such a full cycle process is not used for surface modification, but is used as a deposition process of a simple thin film such as SiO₂ or SiN, and the like.

However, the invention progresses surface modification by a half cycle process wherein the CVD/ALD process is partially modified, instead of a thin film deposition, using the surface modifier of Chemical Formula 1, thus easily applying surface modification for an inorganic film.

Such a substrate surface modifier for atomic layer deposition or chemical vapor deposition of Chemical Formula 1 of the invention is a compound that is deposited on the surface of a substrate by atomic layer deposition (ALD) or chemical vapor deposition (CVD) to change the surface properties of the substrate.

In addition, the substrate surface modifier of Chemical Formula 1 is a gaseous monomolecular compound, and may be used for atomic layer deposition or chemical vapor deposition as explained above.

In addition, the substrate surface modifier may control a surface contact angle (°) of a substrate including a surface modification layer according to the degree of hydrophilicity or hydrophobicity of a subject of which surface is to be modified. Specifically, according to the degree of hydrophilicity or hydrophobicity of a subject of which surface is to be modified, the substrate surface modifier may control such that the surface contact angle of a substrate including a surface modification layer may become 50° or more. In addition, the substrate surface modifier may control such that the surface contact angle of a substrate including a surface modification layer may become less than 50°. Namely, the substrate surface modifier may variously control the surface contact angle according to the property of a substrate, and control the degree of hydrophobicity of a substrate.

Specifically, in case the substrate surface modifier controls such that the surface contact angle of a substrate including a surface modification layer may become less than 50°, it may control such that the contact angle may become less than 50°, or 15° to 50°, or less than 15°, or 5° to 15°.

In addition, in case the substrate surface modifier controls such that the surface contact angle of a substrate including a surface modification layer may become 50° or more, it may control such that the contact angle may become 50° or more, or 50° to 75°, or 75° to 90°, or 90° to 130°.

Thus, by using the substrate surface modifier, in case the surface of a highly hydrophilic substrate is to be hydrophobically modified, substrates having low hydrophobicity, medium hydrophobicity, and high hydrophobicity can be selectively provided. That is to say, the invention can variously control a substrate from hydrophilic to hydrophobic ranges according to desired degree.

In addition, the surface modifier of the invention may also improve adhesion between a substrate and a photoresist.

Specifically, in the substrate surface modifier represented by Chemical Formula 1, L1, L2, L3, and L4 may each independently be a ligand of X, and the functional group modifying the surface of a substrate may be a ligand hydrophobically or hydrophilically modifying the surface of a substrate.

The L1, L2, L3, and L4, which are the ligands of X, may each independently be hydrogen (H); a halogen, for example I; a C1-10 hydrocarbon group, for example a C1-6 hydrocarbon group; a C1-10 alkoxy group, for example a C1-6 alkoxy group; or a C1-10 alkylamino group, for example a C1-6 alkylamino group.

In addition, the L1, L2, L3, and L4 may be identical to or different from each other. Specifically, the L1, L2, L3, and L4 may be identical to one another, or at least one of them may be different. More specifically, when at least one of the L1, L2, L3, and L4 includes a different surface modification functional group, performance as a surface modifier may be further optimized to hydrophobically or hydrophilically modify a substrate surface.

As the halogen, F, Cl, Cr, I, and the like may be used, and for example, it may be I.

The hydrocarbon group may include an aliphatic or aromatic hydrocarbon, and as the examples, alkyl, alkenyl, cyclopentadienyl, aryl, and the like may be included. More specific examples of the hydrocarbon group may include iso-butyl, n-butyl, vinyl, allyl, phenyl, benzyl, cyclopentadienyl, and the like.

In addition, the hydrocarbon group may be substituted with a halogen atom, and specifically, a hydrocarbon such as alkyl, alkenyl, or aryl may be substituted with a halogen, for example F. In this case, the example of the hydrocarbon group may include —CF₃ or pentafluorophenyl (—PhF₅), and the like.

As the examples of the alkoxy group, methoxy, ethoxy, and the like may be included, and as the examples of the alkylamino group, dimethylamine, diethylamine, diisopropylamine, and the like may be included.

As the ligand of X, a ligand hydrophobically or hydrophilically modifying the surface of a substrate, a ligand increasing adhesion between a substrate and a photoresist, and the like may be illustrated.

Specifically, at least one of the L1, L2, L3, and L4 may be a C1-10 hydrocarbon group, and at least one other may be a C1-10 alkylamino group. In this case, the ligands of the surface modifier include at least one hydrocarbon group and at least one alkylamino group, thus providing a highly hydrophobic substrate, for example, a substrate having a contact angle of 50° or more, or 75° to 90°, or 90° to 130°.

At least one of the L1, L2, L3, and L4 may be a C1-10 hydrocarbon group, and at least one other may be halogen. In this case, the ligands of the surface modifier include at least one hydrocarbon group as a hydrophobic functional group and at least one halogen as a hydrophilic functional group, thus providing a substrate having medium hydrophobicity, for example, a substrate having a contact angle of 15° or more, or 15° to 75°.

All the L1, L2, L3, and L4 may be C1-10 hydrocarbon groups, or C1-10 alkoxy groups. In this case, the ligands of the surface modifier are included as hydrophobic functional groups, thus providing a highly hydrophobic substrate, for example, a substrate having a contact angle of 50° or more or 75° to 90°.

At least one of the hydrocarbon groups may be a hydrocarbon group substituted with a halogen atom, and for example, a hydrocarbon group substituted with F. In this case, a highly hydrophobic substrate may be provided.

At least one of the L1, L2, L3, and L4 may be an alkylamino group, and the remainder may be hydrogen. In this case, the ligands of the surface modifier include at least one alkylamino group or hydrogen as a hydrophobic functional group, thus providing a substrate having medium hydrophobicity, for example, a substrate having a contact angle of 15° to 50°, or 50° to 75°.

In addition, as explained above, X may be Si, Ge, Ti, W, Co, Al, Ni, Ru, Cu, Ta, Sn, Hf, La, Mn, Ga, In, or Zr, and for example, X may be Si.

The construction of Chemical Formula 1 may further improve the effects of modifying a substrate surface and improving adhesion to a substrate, and it not only has an excellent substrate surface modification effect, but also affords a desired surface contact angle to a substrate. In addition, even if the surface modifier including the ligands of Chemical Formula 1 is exposed to moisture in the air for more than 24 hours, the modification effect may be maintained.

According to one embodiment, in case a highly hydrophilic oxide film, a nitride film, or an oxynitride film is hydrophobically modified, ligands may be selected according to a desired degree of hydrophobicity of the substrate surface.

In case a substrate having low hydrophobicity is required (contract angle to water is less than 15°, see examples for the measurement method of contact angle), the ligands for surface modification may include a halogen such as Cl, Br, I, and the like as a hydrophilic functional group.

In case a substrate having medium hydrophobicity is required (contact angle to water is 15° or more and less than 75°), the ligands for surface modification may include function groups such as hydrogen (H); a C1-6 alkoxy group; or a C1-6 alkylamino group; and the like.

In this case, the C1-6 alkoxy group may include methoxy, ethoxy, n-propoxy, iso-propoxy, n-butoxy, t-butoxy, sec-butoxy, cyclopentyloxy, cyclohexyloxy, and the like. The C1-6 alkylamino group may include dimethylamino, diethylamino, methylethylamino, di-n-propylamino, di-iso-propylamino, di-t-butylamino, di-sec-butylamino, di-n-butylamino, methylamino, ethylamino, n-propylamino, iso-propylamino, n-butylamino, sec-butylamino, t-butylamino, and the like.

In addition, in case a substrate having high hydrophobicity is required (contact angel to water is 75° or more), the ligands for surface modification may include hydrophobic functional groups such as F (halogen); a C1-10, for example a C1-6 alkyl group; a C1-10, for example a C1-6 alkenyl group; a cyclopentadienyl group; or a C6-10 aryl group; and the like. The C1-10 alkyl group may include methyl, ethyl, n-propyl, isopropyl, n-butyl, iso-butyl, sec-butyl, t-butyl, n-pentyl, sec-pentyl, iso-pentyl, cyclohexyl, and the like. The C1-10 alkenyl group may include vinyl, allyl, and the like. The C6-10 aryl group may include phenyl, benzyl, and the like.

As the examples of the surface modifier represented by Chemical Formula 1, (dimethylamino)trimethylsilane (DMA-Si(Me)₃), bis(diethylamino)dimethylethylsilane (Et-Si(NMe₂)(Me)₂), (diethylamino)trimethylsilane (DEA-Si(Me)₃), tris(dimethylamino)phenylsilane (Ph-Si(N(Me)₂)₃), (dimethylamino)dimethoylphenylsilane (Ph-Si(OMe)₂(NMe₂)), di(iso-butyl)(dimethylamino)phenylsilane (Ph-Si(sBu)₂(NMe₂)), dibutyl(dimethylamino)vinylsilane (Vinyl-Si(ⁿBu)₂(NMe₂), dimethoxy(dimethylamino)vinyl silane (Vinyl-Si(OMe)₂(NMe₂), n-butyldimethyl(dimethylamino)silane (ⁿBu-Si(OMe)₂(NMe₂), methyltriiodosilane (CH₃—Si—I₃), vinytriiodosilane (CH₂═CH—Si—I₃), trimethyl(trifluoromethyl)silane (CF₃—Si—(Me)₃), trimethyl(pentaflurorophenyl)silane (F₅Ph-SiMe₃), tris(dimethylamino)(cyclopentadienyl)zirconium (Zr(C₅H₅)(N(Me)₂)₃), tetrakis(dimethylamino)hafnium(IV) (Hf(N(Me)₂)₄), tetramethylorthosilicate (Si(OMe)₄), tetraethylorthosilicate (Si(OCH₂CH₃)₄), and the like may be illustrated.

More specifically, the surface modifier represented by Chemical Formula 1 may be (diethylamino)trimethylsilane (DEA-Si(Me)₃), tris(dimethylamino)phenylsilane (Ph-Si(N(Me)₂)₃), (dimethylamino)dimethoylphenylsilane (Ph-Si(OMe)₂(NMe₂)), di(iso-butyl)(dimethylamino)phenylsilane (Ph-Si(sBu)₂(NMe₂)), dibutyl(dimethylamino)vinylsilane (Vinyl-Si(ⁿBu)₂(NMe₂), dimethoxy(dimethylamino)vinyl silane (Vinyl-Si(OMe)₂(NMe₂), n-butyldimethyl(dimethylamino)silane (ⁿBu-Si(OMe)₂(NMe₂), methyltriiodosilane (CH₃—Si—I₃), vinytriiodosilane (CH₂═CH—Si—I₃), trimethyl(trifluoromethyl)silane (CF₃—Si—(Me)₃), or trimethyl(pentaflurorophenyl)silane (F₅Ph-SiMe₃).

Such illustrated compounds may form a surface modification layer of a substrate more effectively, and hydrophilically or hydrophobically modify the substrate as needed, thereby realizing an excellent surface contact angle on the substrate, and improving adhesion between a substrate and a photoresist. In addition, the compounds may easily modify the substrate surface, for an inorganic film.

Hereinafter, referring to drawings, the substrate surface modifier and a method for modifying the surface of a substrate of the invention will be explained in more detail.

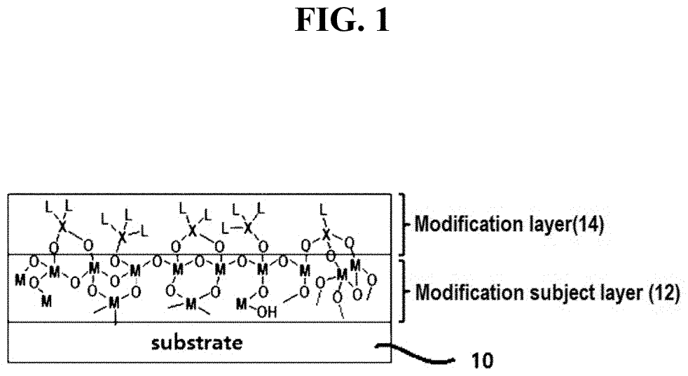

FIG. 1 shows the state of a substrate modified with the substrate surface modifier according to an exemplary embodiment of the invention.

As shown in FIG. 1, on the surface of a substrate (10), a modification subject layer (12) may be positioned if necessary, and on the upper surface of the substrate (10) or the modification subject layer (12), a surface modification layer (14) is positioned. Namely, in the surface-modified substrate of the invention, a surface modification layer may be formed on a substrate, or a surface modification layer may be formed on the upper surface of a modification subject layer formed on the substrate, and more preferably, a surface modification layer may be formed on a modification subject layer, as shown in FIG. 1.

The substrate (10) is any lower part material on which a device, circuit, or membrane may be formed. The modification subject layer (12) may be formed on the substrate (10) for various uses during a semiconductor process, and for example, it may be formed by atomic layer deposition or chemical vapor deposition. In addition, in the present disclosure, the substrate or modification subject layer may be a thin film in need of surface modification.

Specifically, the surface modification layer (14) is a monomolecular layer deposited by atomic layer deposition or chemical vapor deposition so as to invest a modification effect to the surface of the lower modification subject layer (12), and is formed of the substrate surface modifier represented by Chemical Formula 1.

Bonding between the substrate (10) or the modification subject layer (12) and the substrate surface modifier may be achieved by a chemical reaction between the surface modifier and the substrate (10) or the modification subject layer (12), or physical adsorption. In FIG. 1, X is as defined in Chemical Formula 1, L represents the ligand L1, L2, L3, or L4 of Chemical Formula 1, and M is as defined for X in Chemical Formula 1. In FIG. 1, although the modification subject layer (12) is shown as an oxidation film, the modification subject layer (12) is not limited thereto, and it may be a nitride film, an oxynitride film, and the like formed by atomic layer deposition.

Next, a method for modifying the surface of a substrate using the substrate surface modifier according to the invention will be explained.

According to another embodiment of the invention, there is provided a method for modifying the surface of a substrate consisting of steps of: placing a substrate in a deposition chamber, and then supplying a substrate surface modifier in the form of a gas to the deposition chamber, to form a surface modification layer formed of the substrate surface modifier on the surface of the substrate; and supplying a purge gas to the deposition chamber, to remove a surplus of the substrate surface modifier.

In order to modify the surface of a substrate (10) according to the invention, the method includes a step of placing a substrate (10) in an atomic layer deposition or chemical vapor deposition chamber, and then supplying the substrate surface modifier according to the invention in the form of gas to the deposition chamber, thus forming a surface modification layer (14) formed of the substrate surface modifier on the surface of the substrate (10).

In addition, if necessary, on the substrate (10), a modification subject layer, (12) such as an oxide film, a nitride film, an oxynitride film, and the like may be further formed by common atomic layer deposition or chemical vapor deposition.

The modification subject layer may be any inorganic film selected from the group consisting of an oxide film, a nitride film, and an oxynitride film. Specifically, the modification subject layer may be inorganic film such as SiO₂, SiN, SiON, SnO₂, HfO₂, ZrO₂, and the like, and various other inorganic films may be used as the modification subject layer.

Herein, it is preferable that the step of forming the surface modification layer includes conducting a deposition process at least once. Specifically, the deposition process of the surface modifier may be repeatedly conducted one or more times such that the surface modification layer may completely cover the surface of the substrate or modification subject layer. Specifically, the deposition process of the surface modifier may be repeatedly conducted 1 to 10 times. For example, the deposition process of the surface modifier may be repeatedly conducted 2 to 10 times, or 3 to 10 times.

In addition, after the surface modification layer is formed, the surface modifier may remain after the surface modification reaction is completed, and thus it is preferable to remove the surplus of the substrate surface modifier included in the deposition chamber. For example, the surplus of the substrate surface modifier may be removed by introducing an inert gas for purging in the deposition chamber.

The modification subject layer may be formed on the substrate by well known methods, before forming the surface modification layer.

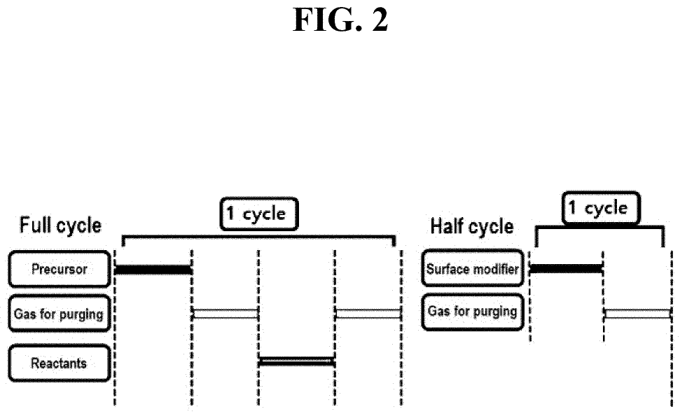

FIG. 2 shows the method for modifying a substrate surface using the substrate surface modifier according to an exemplary embodiment of the invention.

Specifically, FIG. 2 shows a method for surface modification, using the substrate of FIG. 1, on which a modification subject layer is formed.

Thus, the method for modifying a substrate surface of the invention includes steps of: forming a modification subject layer on a substrate; and forming a surface modification layer on the surface of the modification subject layer as explained above.

As the method for forming a modification subject layer on a substrate before modifying the substrate surface, atomic layer deposition that is well known in the art may be used. In addition, the surface modification layer may be formed by chemical vapor deposition.

For example, according to an example of atomic layer deposition, a 4-step process of supplying a precursor, purging, supplying reactants, and purging (referred to as ‘full cycle’ herein) is conducted to form a modification subject layer (12) at the level of a molecular layer on the top of the substrate (10). Depending on the repeat number of such a full cycle process, the thickness of the modification subject layer (12) may be adjusted.

Such a modification subject layer may be formed by atomic layer deposition including steps of: adsorbing a substrate surface modifier for forming a modification subject layer, on top of a substrate placed in a deposition chamber; supplying an inert gas for purging to the deposition chamber, to remove a surplus of the substrate surface modifier that is not adsorbed to the substrate; supplying reactants that react with the substrate surface modifier to form a modification subject layer to the deposition chamber, to form a modification subject layer; and supplying purge gas again to the deposition chamber, to remove unreacted reactants.

More specifically, in order to form a modification subject layer (12) by atomic layer deposition, as shown in the left side of FIG. 2, a substrate (1) is placed in a deposition chamber, and a precursor for forming a modification subject layer (12) is supplied to the deposition chamber as first raw materials, to adsorb the precursor on top of the substrate (10). Next, an inert purge gas such as nitrogen (N₂), argon (Ar₂), and the like, is supplied to the deposition chamber, to remove a surplus of the precursors not adsorbed to the substrate (10). Next, second raw materials (reactants) that react with the first raw materials to form a modification subject layer (12) such as an oxide film, a nitride film, an oxynitride film, and the like, are supplied to the deposition chamber, to form a modification subject layer (12). The reactant varies based on the kind of a precursor used and a thin film to be produced, and generally, it is gas containing O, N, H, and the like, or plasma generated using the same. Next, a purge gas is supplied again to the deposition chamber to remove unreacted second raw materials (reactants).

In addition, a method for forming a surface modification layer on the modification subject layer is not the 4-step full cycle as explained above, but is a 2-step process of introducing a gaseous surface modifier and a purge gas.

Namely, the method for modifying a substrate surface according to the invention is conducted by a 2-step process wherein a substrate (10) is placed in a deposition chamber, and then, as shown in the right side of FIG. 2, a substrate surface modifier is supplied to form a surface modification layer (14) formed of the substrate surface modifier on the surface of the substrate (10) or a modification subject layer (12), and then a purge gas is supplied to the deposition chamber to remove a surplus of the substrate surface modified (referred to as a ‘half cycle’ herein). The half cycle may mean a deposition process of the surface modifier as explained above. Thus, the invention may control the degree of deposition and thickness of the surface modification layer (14) based on the number of repetition of the half cycle process. Such a half cycle process may be repeatedly conducted 2 to 10 times, for example 3 to 7 times.

Meanwhile, as in common atomic layer deposition, if deposition of a surface modifier is completed as a full cycle wherein a reactant is introduced lastly, the top layer, i.e., the modification subject layer (12) that is formed may have low surface energy and high polarity due to the reactant.

In addition, if deposition of a surface modifier is completed as a half cycle, the ligand (L) of the substrate surface modifier does not react with the reactant and remains on the surface of the substrate (10), and thus an appropriate ligand (L) may be selected to control surface energy and polarity, thus modifying the surface of a substrate (10).

In addition, the formation of a modification subject layer and the formation of a surface modification layer according to the invention, as explained above, may be conducted as a continuous process.

As explained above, according to the invention, a surface modification layer (14) is formed by atomic layer deposition or chemical vapor deposition that is considered most precise among the current thin film deposition methods, and thus, a very uniform and high density monomolecular layer surface modification layer (14) may be obtained, and simultaneously, the surface modification effect is superior to the existing surface modifier coating method. In addition, recently, since a subject layer (12) is often formed by atomic layer deposition, a surface modification layer (14) can be continuously formed using the same atomic layer deposition equipment, without a need to change equipment so as to form a surface modification layer (14). Thus, unnecessary outside exposure of the substrate (10) can be prevented, and the resulting advantages in terms of time, cost, and quality can be obtained.

Hereinafter, the invention will be explained in more detail through specific examples. However, these examples are presented only as the illustrations of the invention, and the invention is not limited thereby.

### EXAMPLE 1: SURFACE MODIFICATION OF SiO₂ THIN FILM

Using a traveling mode 4″ atomic layer deposition device (CN-1 Co. Ltd.), on a silicon substrate, a relatively thick modification subject layer (10 nm) and a surface modification layer of molecular layer thickness (thin film stack) were sequentially deposited. In order to prevent water contamination due to exposure to the air and simplify the process, while the silicon substrate was always maintained in the vacuum chamber of a deposition device, the deposition processes of the modification subject layer and the surface modification layer were continuously progressed by an in-situ method. Specific deposition processes are as follows.

First, a silicon substrate was treated with an aqueous solution of 10 wt % HF for 1 minute to remove a naturally occurring oxide film on the surface, and then cleaned with distilled water and dried with nitrogen, thus preparing a substrate for atomic layer deposition. In order to form a SiO₂ thin film as a modification subject layer, the substrate was placed in a reactor, and then a 4-step process of (1) introducing diisopropylaminosilane (DIPAS) as a silicon precursor for atomic layer deposition, (2) purging with an inert gas (N₂) for removal of a surplus precursor and by-products, (3) introducing O₃ gas as reactant, and (4) purging with an inert gas (N₂) for removal of a surplus reactant and by-products were sequentially repeated to deposit a SiO₂ thin film with a total thickness of 10 nm. The temperature of the substrate was maintained at 300° C., and a duration of each step, a flow rate of a purge gas, and the like were optimized in the experiment equipment. As the energy source required for the deposition reaction, plasma was not used, and only heat energy was used by heating of the substrate.

After deposition of the modification subject layer (SiO₂ thin film) was completed, while the substrate was maintained in the deposition chamber without being exposed outside, five (5) kinds of compounds represented by the following Chemical Formulas 1a to Chemical Formula 1e were respectively used as a surface modifier to deposit a surface modification layer. Since the surface modifier is deposited only as a monomolecular layer, unlike common 4-step full atomic layer deposition, half cycle deposition consisting of introduction of the surface modifier and the subsequent purging was conducted. It omits the steps (3) and (4) of the 4-step process for depositing a modification subject layer. Since the deposition process of the surface modification layer is a self-limiting reaction, a maximum of 1 molecular layer is formed on top of the stack. The deposition process using the surface modifier was repeatedly conducted N times (N-1,3,5,10) so as to completely cover the surface of the modification subject layer.

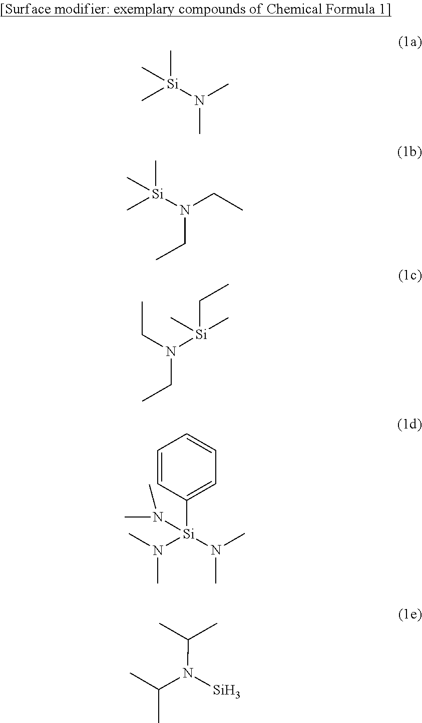

### EXAMPLE 2: SURFACE MODIFICATION OF SiN THIN FILM

Using DIPAS and HCP (Hollow Cathode Plasma), NH₃ plasma respectively as a precursor and a reactant, a SiN thin film with a thickness of 10 nm was deposited as a modification subject layer, and the surface of the SiN thin film was modified by the same method as Example 1, except that compounds represented by Chemical Formula 1b and Chemical Formula 1d were respectively used as a surface modifier.

### EXAMPLE 3: SURFACE MODIFICATION OF SiON THIN FILM

Using DIPAS and ICP (Inductively Coupled Plasma) NH₃ plasma respectively as a precursor and a reactant, a SiON thin film with a thickness of 10 nm was deposited as a modification subject layer, and the surface of the SiON thin film was modified by the same method as Example 1, except that compounds represented by Chemical Formula 1b and Chemical Formula 1d were respectively used as a surface modifier.

### EXAMPLE 4: SURFACE MODIFICATION OF SiO₂ THIN FILM

Using tetrakis (dimethylamino)tin(IV) (TDMA-Sn) and H₂O respectively as a precursor and a reactant, a SiO₂ thin film with a thickness of 10 nm was deposited as a modification subject layer, and the surface of the SiO₂ thin film was modified by the same method as Example 1, except that compounds represented by Chemical Formula 1b and Chemical Formula 1d were respectively used as a surface modifier.

### EXAMPLE 5: SURFACE MODIFICATION OF HfO₂ THIN FILM

Using tetrakis(ethylmethylamido)hafnium(IV) (TEMA-Hf) and H₂O respectively as a precursor and a reactant, a HfO₂ thin film with a thickness of 10 nm was deposited as a modification subject layer, and the surface of the HfO₂ thin film was modified by the same method as Example 1, except that compounds represented by Chemical Formula 1b and

Chemical Formula 1d were respectively used as a surface modifier.

### EXAMPLE 6: SURFACE MODIFICATION OF ZrO₂ THIN FILM

Using TEMA-Zr and H₂O respectively as a precursor and a reactant, a ZrO₂ thin film with a thickness of 10 nm was deposited as a modification subject layer, and the surface of the ZrO₂ thin film was modified by the same method as Example 1, except that compounds represented by Chemical Formula 1b and Chemical Formula 1d were respectively used as a surface modifier.

### Comparative Examples 1 to 6: Deposition of Non-Surface-Modified Thin Film

A modification subject layer was deposited on a substrate respectively by the same method as Examples 1 to 6, except that the surface modification process was not conducted.

### Experimental Example 1: Confirmation of Surface Modification Effect Through Measurement of Water Contact Angle

By measuring an angle formed by a water drop falling on a substrate (water contact angle), the degree of hydrophilicity of a substrate surface can be seen, and surface polarity can be seen therefrom.

Thus, by measuring the water contact angle of each thin film manufactured in Examples 1 to 6 and Comparative Examples 1 to 6, polarity change by modification, i.e., whether or not modification occurred, and the degree of modification were investigated, and the results are shown in the following Table 1.

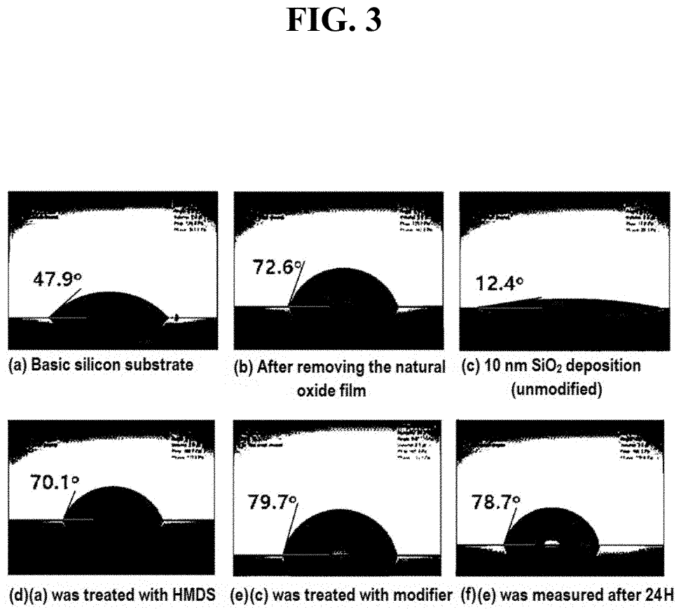

Meanwhile, the contact angle of a silicon substrate having a naturally occurring oxide film was 47.9° (FIG. 3 (a)), and in case the naturally occurring oxide film was completely removed by cleaning with hydrofluoric acid, the silicone substrate has a hydrophobic surface with a contact angle of 72.6° (FIG. 3(b)). The silicon substrate is originally non-polar (hydrophobic), but if the substrate surface is oxidized and a naturally occurring oxide film is formed, the polarity of the substrate surface relatively increases (hydrophilic).

TABLE 1

| Modification | | | Contact angle (°) | Contact angle (°) |
|---|---|---|---|---|
| subject layer | | Modifier | (deg, immediately) | (deg, after 24 H) |
| SiO₂ | Comparative | Not modified | 12.4 | 13.1 |
| | Example 1 | | | |
| | Example 1 | Chemical Formula 1a | 79.7 | 78.7 |
| | | Chemical Formula 1b | 79.3 | 79.5 |
| | | Chemical Formula 1c | 80.1 | 79.9 |
| | | Chemical Formula 1d | 84.7 | 84.6 |
| | | Chemical Formula 1e | 69.8 | 69.6 |
| SiN | Comparative | Not modified | 22.1 | 22.6 |
| | Example 2 | | | |
| | Example 2 | Chemical Formula 1b | 80.4 | 79.6 |
| | | Chemical Formula 1d | 85.1 | 85.4 |
| SiON | Comparative | Not modified | 15.4 | 14.8 |
| | Example 3 | | | |
| | Example 3 | Chemical Formula 1b | 79.6 | 80.2 |
| | | Chemical Formula 1d | 84.4 | 84.9 |
| SnO₂ | Comparative | Not modified | 8.6 | 9.2 |
| | Example 4 | | | |
| | Example 4 | Chemical Formula 1b | 80.3 | 79.7 |
| | | Chemical Formula 1d | 84.8 | 84.2 |
| HfO₂ | Comparative | Not modified | 15.3 | 14.7 |
| | Example 5 | | | |
| | Example 5 | Chemical Formula 1b | 81.1 | 80.7 |
| | | Chemical Formula 1d | 85.3 | 85.1 |
| ZrO₂ | Comparative | Not modified | 14.6 | 14.8 |
| | Example 6 | | | |
| | Example 6 | Chemical Formula 1b | 80.2 | 80.5 |
| | | Chemical Formula 1d | 84.9 | 85.5 |

As shown in the Table 1, when SiO₂ was deposited by atomic layer deposition, a contact angle decreased to nearly 10°, thus forming a hydrophilic surface (FIG. 3(c), Comparative Example 1). Namely, if an oxide film is formed more densely and thickly than a naturally occurring oxide film by atomic layer deposition, the polarity (hydrophilicity) of the substrate surface increases compared to a substrate of a natural state. If the polarity of the substrate surface increases, adhesion may be lowered when coating of a low polar thin film, and thus, in a common semiconductor process, when depositing a thin film on a silicon substrate, an adhesion promoter such as hexamethyldisilazane (HMDS) is coated on a silicon substrate to increase bonding strength of a silicon substrate. The water contact angle of a silicon substrate coated with HMDS is commonly about 70° (FIG. 3 (d)), which is almost similar to that of a pure silicon substrate removed of a naturally occurring oxide film.

In addition, if an atomic layer deposited SiO₂ thin film with a thickness of 10 nm is modified with a surface modifier represented by Chemical Formula 1a (Example 1), the contact angle is about 80° (FIG. 3(e)), which is about 10° larger than the contact angle of the HMDS coated surface. Thus, it can be seen that the surface modifier represented by Chemical Formula 1a has a surface hydrophobicizing (low polarization) effect equivalent to or more excellent than HMDS.

In addition, in order to confirm durability of a modification effect when exposed to moisture in the air, 24 hours after completing modification in Example 1, the contact angle was measured by the same method. As the result, it can be seen that in Example 1, the contact angle changed little (FIG. 3(f)), or by a small degree (Chemical Formula 1e), or a modification effect lasted for more than 24 hours.

According to the Table 1, even when the modification subject layers are different (Examples 2 to 6, Comparative Examples 2 to 6), substantially the same results as Example 1 and Comparative Example 1 were exhibited. Namely, in case the surface modifier represented by Chemical Formula 1b was used, a surface contact angle was about 80°, and in case the surface modifier represented by Chemical Formula 1d was used, a surface contact angle was about 85°, and the contact angles were maintained even after 24 hours. Thus, it can be seen that the contact angle of the modified substrate surface is unrelated to the composition of the modification subject layer, but varies according to the kind of the surface modifier.

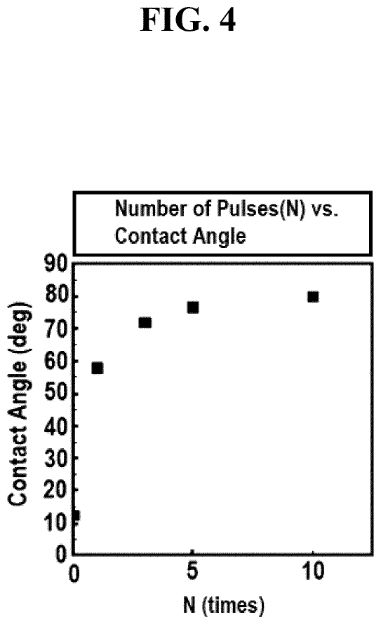

Meanwhile, the experimental results of contact angle when the surface modifier is deposited N times (N=1, 3, 5, 10) each for one second, are shown in FIG. 4. As shown in FIG. 4, it can be seen that if the surface modifier is introduced more than 5 times each second, the contact angle is saturated.

Thus, the invention enables a half cycle process, and can uniformly modify the surface of a substrate for atomic layer deposition or chemical vapor deposition, by applying the surface modifier of Chemical Formula 1. In addition, the invention can be easily applied for an inorganic film, instead of the existing organic polymer film for surface modification, and can prevent damage of equipment used in the process.

What is claimed is:

1. A substrate surface modifier for atomic layer deposition or chemical vapor deposition represented by the following Chemical Formula 1: 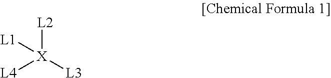
wherein,
X is Si, Ge, Ti, W, Co, Al, Ni, Ru, Cu, Ta, Sn, Hf, La, Mn, Ga, In, or Zr; and
L1, L2, L3, and L4 are each independently a ligand of X, and at least one of the L1, L2, L3, and L4 comprises a functional group modifying the surface of a substrate, and at least one other of the L1, L2, L3, and L4 comprises a functional group bonding to the surface of a substrate.

2. The substrate surface modifier for atomic layer deposition or chemical vapor deposition according to claim 1, wherein the functional group modifying the surface of a substrate is a ligand hydrophobically or hydrophilically modifying the surface of a substrate.

3. The substrate surface modifier for atomic layer deposition or chemical vapor deposition according to claim 1, wherein the substrate surface modifier causes a surface contact angle of a substrate including a surface modification layer to become 50° or greater.

4. The substrate surface modifier for atomic layer deposition or chemical vapor deposition according to claim 1, wherein the L1, L2, L3, and L4 are each independently hydrogen, a halogen, a C1-10 hydrocarbon group, a C1-10 alkoxy group, or a C1-10 alkylamino group.

5. The substrate surface modifier for atomic layer deposition or chemical vapor deposition according to claim 4, wherein the hydrocarbon group is an alkyl, alkenyl, cyclopentadienyl, or aryl group.

6. The substrate surface modifier for atomic layer deposition or chemical vapor deposition according to claim 1, wherein the L1, L2, L3, and L4 are identical to one another, or at least one of the L1, L2, L3, and L4 is different.

7. The substrate surface modifier for atomic layer deposition or chemical vapor deposition according to claim 1, wherein at least one of the L1, L2, L3, and L4 is a C1-10 hydrocarbon group, and at least another one is a C1-10 alkylamino group.

8. The substrate surface modifier for atomic layer deposition or chemical vapor deposition according to claim 1, wherein at least one of the L1, L2, L3, and L4 is a C1-10 hydrocarbon group, and at least another one is a halogen.

9. The substrate surface modifier for atomic layer deposition or chemical vapor deposition according to claim 1, wherein all of the L1, L2, L3, and L4 are C1-10 hydrocarbon groups, or C1-10 alkoxy groups.

10. The substrate surface modifier for atomic layer deposition or chemical vapor deposition according to claim 9, wherein at least one of the hydrocarbon groups is a hydrocarbon group substituted with a halogen atom.

11. The substrate surface modifier for atomic layer deposition or chemical vapor deposition according to claim 1, wherein the surface modifier represented by Chemical Formula 1 is selected from the group consisting of (dimethylamino)trimethylsilane, bis(diethylamino)dimethylethylsilane, (diethylamino)trimethylsilane, tris(dimethylamino)phenylsilane, (dimethylamino)dimethoxyphenylsilane, di(isobutyl)(dimethylamino)phenylsilane, dibutyl(dimethylamino)vinylsilane, vinyl(dimethylamino)dimethoxysilane, n-butyldimethyl(dimethylamino)silane, methyltriiodosilane, vinyltriiodosilane, trimethyl(trifluoromethyl)silane, trimethyl(pentafluorophenyl)silane, tris(dimethylamino)(cyclopentadienyl)zirconium, tetrakis(dimethylamino)hafnium, tetramethylorthosilicate, and tetraethylorthosilicate.

12. A method for modifying a surface of a substrate, the method consisting of:
placing a substrate in a deposition chamber, and supplying a substrate surface modifier in the form of gas to the deposition chamber, thereby forming a surface modification layer formed by the substrate surface modifier on a surface of the substrate; and
supplying a purge gas to the deposition chamber, thereby removing a surplus of the substrate surface modifier.

13. The method for modifying a surface of a substrate according to claim 12, wherein the supply of the surface modifier and the supply of the purge gas are repeatedly conducted 2 to 10 times.

14. The method for modifying a surface of a substrate according to claim 12, wherein a modification subject layer, which is an inorganic film, is formed on the substrate.

15. The method for modifying a surface of a substrate according to claim 14, wherein the modification subject layer is any one inorganic film selected from the group consisting of an oxide film, a nitride film, and an oxynitride film.

16. The method for modifying a surface of a substrate according to claim 14, wherein the modification subject layer is formed by an atomic layer deposition method that comprises:
adsorbing a substrate surface modifier for forming a modification subject layer on top of the substrate placed in the deposition chamber;
supplying an inert purge gas to the deposition chamber, thereby removing a surplus of the substrate surface modifier that is not adsorbed to the substrate;
supplying reactants that react with the substrate surface modifier to form a modification subject layer to the deposition chamber, thereby forming a modification subject layer; and
supplying a purge gas to the deposition chamber, thereby removing unreacted reactants.
